(19) United States
(12) Patent Application Publication
(10) Pub. No.: US 2025/0285819 A1
(43) Pub. Date: Sep. 11, 2025

(54) ELECTRICAL SWITCH UNIT FOR ELECTRICAL DEVICE

(71) Applicant: DEFOND ELECTECH CO., LTD, Dongguan (CN)

(72) Inventors: Kin Yu WONG, Dongguan (CN); Wei Hai PAN, Dongguan (CN); Chiu Keung LOONG, Dongguan (CN); Cheng Chen NIEH, Dongguan (CN); Jian Xin WU, Dongguan (CN); Lap Yi LAW, Dongguan (CN); Pat On KWOK, Dongguan (CN)

(73) Assignee: DEFOND ELECTECH CO., LTD, Dongguan (CN)

(21) Appl. No.: 18/920,677

(22) Filed: Oct. 18, 2024

(30) Foreign Application Priority Data
Mar. 8, 2024 (CN) 2024102694720

(51) Int. Cl. H01H 9/02; H01H 1/14; H05K 1/18

(52) U.S. Cl. CPC H01H 9/02; H01H 1/14; H05K 1/181; H05K 2201/10022

(57) ABSTRACT

Disclosed is an electrical switch unit for an electrical device, including a shell and a signaling module. The shell accommodates an actuator movably installed in the shell. The signaling module includes a circuit board, including a first region provided with a variable resistor element, the variable resistor element having a contact surface of the variable resistor element; a film, including a first film contact surface and a second film contact surface, the first film contact surface of the film having a first conducting layer and the conducting layer of the first film contact surface being spaced from the contact surface of the variable resistor element through a spacer element; and a moving component operably connected to the actuator and capable of promoting the conducting layer of the first film contact surface to form contact with the contact surface of the variable resistor element in a plurality of contact point structures.

### RELATED APPLICATIONS

The present patent document claims the benefit of priority to Patent Application No. CN 2024102694720, filed Mar. 8, 2024, and entitled “ELECTRICAL SWITCH UNIT FOR ELECTRICAL DEVICE,” the entire contents of which are incorporated herein by reference.

### BACKGROUND

### 1. Technical Field

The present invention relates to an electrical switch unit for an electrical device such as an electrical device and a garden tool.

### 2. Background Information

Some electrical devices, for example, electric tools and electrical garden tools, convert inputted DC power into mechanical power in the form of output torque or movement by using a brushed or brushless DC motor. Usually, the electrical device includes: a variable speed trigger mechanism; an electrical switch contact, used for selectively connecting and cutting off a DC power supply and a DC motor in response to the movement of an actuator of the variable speed trigger mechanism; a motor signaling circuitry, used for transmitting an electrical signal that indicates a DC motor speed required in response to the movement of the actuator; and a motor control circuit, including a power switch device, used for selectively activating a stator winding input of the DC motor in response to the signal received from the motor signaling circuitry to enable the DC motor to operate at the required speed.

Conventional speed control in the electrical device is realized by a potentiometer or a similar apparatus. Such a potentiometer or similar apparatus is provided with a variable resistor arranged on a printed circuit board, for example, film carbon. For example, in response to the movement of the actuator, the effective resistance of the film carbon can be changed by sliding a conducting sliding blade of the potentiometer on the surface of the film carbon. A variable voltage measured by a variable resistor can be used as a basis for indicating the movement of the actuator and controlling the speed of an electric motor. Because the film carbon is subjected to repeated sliding movement of the conducting sliding blade, the film carbon and the conducting sliding blade may experience considerably great wear, which may eventually result in an inaccurate or unstable speed control operation. Besides, the film carbon is often exposed to pollutant particles, and these pollutant particles not only have a tendency to short-circuit a path line on a conducting sliding blade, but also may aggravate the damage caused by scraping of the conducting sliding blade along the film carbon.

The US patent for invention U.S. Pat. No. 10,547,257B2 previously applied by the applicant discloses a variable speed controller for an electrical device. The presence of a film between a variable resistor element and a slide block contributes to alleviating the wear between a contact surface of the variable resistor element and the slide block because they are not in direct physical contact. Therefore, compared with a variable speed controller of a conventional type, the reliability and stability of operations of the variable speed controller can be maintained within a longer duration of use. Besides, the presence of the film can further contribute to preventing pollutants from accidentally short-circuiting the path line on the contact surface of the variable resistor element, thus, contributing to alleviating the unstable or inaccurate operations of the variable speed controller.

The contact surface of the variable resistor element in the patent includes a first region and a second region, where the first region and the second region are arranged as at least one of the structures in serial and parallel structures relative to each other. It is needed to selectively bridge different path lines in the first region to a conducting layer in the second region to selectively apply a variable voltage to an input pin of an integrated circuit chip, so as to change the speed of the electric motor. However, because the path lines in the first region and the conducting layer in the second region are arranged parallelly in the same plane, in this way, the space needed is relatively large, and the cost of materials is relatively high.

### BRIEF SUMMARY

The present invention aims to relieve at least one of the above problems.

Several broad forms are involved in the present invention. Embodiments of the present invention can include one or any combination of different broad forms described herein.

In a first broad form, the present invention provides an electrical switch unit for an electrical device, the electrical switch unit being used for controlling an operation of a DC motor of the electrical device, where the electrical switch unit includes:
a shell, where the shell accommodates an actuator movably installed in the shell, the actuator being configured to be capable of moving toward an ON position from an OFF position in a direction toward an interior of an opening in the shell along a moving axis and to be capable of moving toward the OFF position from the ON position in a direction toward an exterior of the opening in the shell along the moving axis in response to operations of a finger-operable trigger; and
a signaling module, where the signaling module is associated with the electrical switch unit and includes a signaling circuit, the signaling circuit being used for sensing a movement of the actuator and outputting a signaling module signal that indicates the movement or position of the sensed actuator;
the signaling module includes:
a circuit board, where the circuit board includes a first region provided with a variable resistor element, the variable resistor element having a contact surface of the variable resistor element;
a film, where the film includes a first film contact surface and a second film contact surface, the first film contact surface of the film having a first conducting layer, the conducting layer of the first film contact surface being spaced from the contact surface of the variable resistor element through a spacer element and thus, space being formed therebetween, and one end of the first conducting layer of the first film contact surface being electrically connected to the circuit board; and
a moving component operably connected to the actuator, where, thus, the moving component moves relative to the second film contact surface of the film in response to the movement of the actuator and is capable of promoting the first conducting layer of the first film contact surface to form contact with the contact surface of the variable resistor element in a plurality of contact point structures, and thus, effective resistance of the variable resistor element is configured to change in response to promoting the first conducting layer of the first film contact surface to form contact with the contact surface of the variable resistor element in each of the plurality of contact point structures.

Preferably, the variable resistor element is a continuous variable resistor or is connected by connecting a plurality of fixed resistors in series.

Preferably, an exhaust hole that passes through upper and lower surfaces of the circuit board is formed at a position of the circuit board corresponding to the space.

Preferably, one end of the first conducting layer of the first film contact surface is in contact connection with the circuit board.

Preferably, the end of the first conducting layer of the first film contact surface corresponding to the second film contact surface is configured with a contact spring, and under a pressure of the contact spring, the end of the first conducting layer of the first film contact surface can be promoted to be in contact connection with the circuit board.

Further preferably, the end of the first conducting layer of the first film contact surface is bonded to the circuit board through a conducting bonding layer.

Preferably, the electrical switch unit further includes:
a pair of electrical switch contacts, where at least one of the pair of electrical switch contacts is operably connected to the actuator; in response to the movement of the actuator from the OFF position to the ON position along the moving axis, the pair of electrical switch contacts is arranged as a closed structure, and power can be supplied to the DC motor from a DC power supply via the pair of electrical switch contacts; and in response to the movement of the actuator from the ON position to the OFF position along the moving axis, the pair of electrical switch contacts is arranged as an opened structure, and in this case, power cannot be supplied to the DC motor from the DC power supply via the pair of electrical switch contacts;
a power module, where the power module includes at least one solid state power switch device for supplying the power from the DC power supply to the DC motor controllably; and
a control module, where the control module includes a control circuit, the control circuit being used for receiving the signaling module signal and outputting a control module signal in response to the received signaling module signal to control the at least one solid state power switch device of the power module, where the at least one solid state power switch device supplies the power from the DC power supply to the DC motor controllably to allow the DC motor to operate at a speed corresponding to the movement or position of the sensed actuator.

In another broad form, the present invention provides an electrical switch unit for an electrical device, the electrical switch unit being used for controlling an operation of a DC motor of the electrical device, where the electrical switch unit includes:
a shell, where the shell accommodates an actuator movably installed in the shell, the actuator being configured to be capable of moving toward an ON position from an OFF position in a direction toward an interior of an opening in the shell along a moving axis and to be capable of moving toward the OFF position from the ON position in a direction toward an exterior of the opening in the shell along the moving axis in response to operations of a finger-operable trigger; and
a signaling module, where the signaling module is associated with the electrical switch unit and includes a signaling circuit, the signaling circuit being used for sensing a movement of the actuator and outputting a signaling module signal that indicates the movement or position of the sensed actuator;
the signaling module includes:
a circuit board, where the circuit board includes a first region provided with a variable resistor element and a second region having a signal control element, the first region and the second region being arranged to be physically separated and spaced, the variable resistor element having a contact surface of the variable resistor element, and the signal control element having a contact surface of the signal control element;
a film, where the film includes a first film contact surface and a second film contact surface, the first film contact surface of the film having a first conducting layer and a second conducting layer, the first conducting layer and the second conducting layer of the first film contact surface being spaced from the contact surface of the variable resistor element and the contact surface of the signal control element through spacer elements, respectively and thus, space being formed therebetween, and one end of each of the first conducting layer and the second conducting layer of the first film contact surface being electrically connected to the circuit board; and
a moving component operably connected to the actuator, where, thus, the moving component moves relative to the second film contact surface of the film in response to the movement of the actuator and is capable of promoting the first conducting layer of the first film contact surface to form contact with the contact surface of the variable resistor element in a plurality of contact point structures, and thus, effective resistance of the variable resistor element is configured to change in response to promoting the first conducting layer of the first film contact surface to form contact with the contact surface of the variable resistor element in each of the plurality of contact point structures.

In response to the movement of the moving component along the second film contact surface of the film and the capability of promoting the second conducting layer of the first film contact surface to form contact with the contact surface of the signal control element in a plurality of contact point structures, thus, effective resistance of the signal control element is configured to change in response to promoting the second conducting layer of the first film contact surface to form contact with the contact surface of the signal control element in each of the plurality of contact point structures; or a circuit of the signal control element is configured to switch signals in response to promoting the second conducting layer of the first film contact surface to form contact with the contact surface of the signal control element in one of the plurality of contact point structures.

Preferably, the variable resistor element is a continuous variable resistor or is connected by connecting a plurality of fixed resistors in series.

Preferably, the signal control element is a continuous variable resistor or is connected by connecting a plurality of fixed resistors in series or is an NC/NO switching circuit.

Preferably, the moving component is a rolling element, the rolling element including a first rolling portion and a second rolling portion, the first rolling portion being configured to promote the first conducting layer to form contact with the contact surface of the variable resistor element, and the second rolling portion being configured to promote the second conducting layer to form contact with the contact surface of the signal control element.

Preferably, an exhaust hole that passes through upper and lower surfaces of the circuit board is formed at a position of the circuit board corresponding to the space.

Preferably, the end of each of the first conducting layer and the second conducting layer of the first film contact surface is in contact connection with the circuit board.

Typically, the end of each of the first conducting layer and the second conducting layer of the first film contact surface corresponding to the second film contact surface is configured with a contact spring, and under a pressure of the contact spring, the end of each of the first conducting layer and the second conducting layer of the first film contact surface can be promoted to be in contact connection with the circuit board.

Further preferably, the end of each of the first conducting layer and the second conducting layer of the first film contact surface is bonded to the circuit board through a conducting bonding layer.

Preferably, the electrical switch unit further includes:
a pair of electrical switch contacts, where at least one of the pair of electrical switch contacts is operably connected to the actuator; in response to the movement of the actuator from the OFF position to the ON position along the moving axis, the pair of electrical switch contacts is arranged as a closed structure, and power can be supplied to the DC motor from a DC power supply via the pair of electrical switch contacts; and in response to the movement of the actuator from the ON position to the OFF position along the moving axis, the pair of electrical switch contacts is arranged as an opened structure, and in this case, power cannot be supplied to the DC motor from the DC power supply via the pair of electrical switch contacts;
a power module, where the power module includes at least one solid state power switch device for supplying the power from the DC power supply to the DC motor controllably; and
a control module, where the control module includes a control circuit, the control circuit being used for receiving the signaling module signal and outputting a control module signal in response to the received signaling module signal to control the at least one solid state power switch device of the power module, where the at least one solid state power switch device supplies the power from the DC power supply to the DC motor controllably to allow the DC motor to operate at a speed corresponding to the movement or position of the sensed actuator.

### BRIEF DESCRIPTION OF THE DRAWINGS

The present invention will be more fully understood from the following detailed description of preferred non-limiting embodiments described with reference to drawings, where:

FIGS. 1A-1B respectively show a stereogram and an exploded view of an electrical switch unit that is a signal switch in a first embodiment; by pressing a trigger with a finger of a user, an actuator moves from an OFF position to an ON position inward along a moving axis (X-X′) relative to an opening in a shell; when the finger of the user releases the trigger, through a reset spring, the reset spring promotes the actuator to move outward from the ON position to the OFF position along the moving axis (X-X′) relative to the opening in the shell;

FIGS. 2A-2C respectively show a stereogram, an exploded view, and a section view of an electrical switch unit that is a signal switch in the first embodiment; by pressing the trigger with the finger of the user, the actuator moves from the OFF position to the ON position inward along the moving axis (X-X′) relative to the opening in the shell; when the finger of the user releases the trigger, through a reset spring, the reset spring promotes the actuator to move outward from the ON position to the OFF position along the moving axis (X-X′) relative to the opening in the shell;

FIGS. 3A-3B respectively show a stereogram and an exploded view of assembly of a signaling module and the actuator in the first embodiment; by pressing the trigger with the finger of the user, the actuator moves from the OFF position to the ON position along the moving axis (X-X′); when the finger of the user releases the trigger, through a reset spring, the reset spring promotes the actuator to move outward from the ON position to the OFF position along the moving axis (X-X′);

FIGS. 4A-4B show a perspective view of an operating sequence of the signaling module in the first embodiment, where a rolling element is connected with the second film contact surface in a rolling manner, and thus, the rolling element promotes a first conducting layer and a second conducting layer on the first film contact surface to be in contact with a contact surface of a variable resistor element and a contact surface of a signal control element, respectively, and where the rolling element in FIG. 4A is at the ON position, and the rolling element in FIG. 4B is at the OFF position;

FIGS. 4C-4F respectively show an exploded view and an assembly view of the signaling module in the first embodiment at the ON and OFF positions, where the signaling module includes the rolling element, a film, spacer elements, the contact surface of the variable resistor element, and the contact surface of the signal control element, and where the rolling element in FIG. 4C and FIG. 4E is at the ON position, and the rolling element in FIG. 4D and FIG. 4E is at the OFF position;

FIGS. 5A-5D show a side view of the signaling module in the first embodiment, where, when the rolling element rolls on the second film contact surface, a first rolling portion of the rolling element promotes the first conducting layer to form contact with the contact surface of the variable resistor element and a second rolling portion of the rolling element promotes the second conducting layer to form contact with the contact surface of the signal control element, and where FIG. 5A and FIG. 5C show that one end of the first conducting layer or the second conducting layer is in crimp connection to a circuit board through a contact spring, the variable resistor element or the signal control element in FIG. 5A is connected by connecting a plurality of fixed resistors in series, and the variable resistor element or the signal control element in FIG. 5C is a continuous variable resistor; FIG. 5B and FIG. 5D show that one end of the first conducting layer or the second conducting layer is bonded to the circuit board through a conducting bonding layer, the variable resistor element or the signal control element in FIG. 5B is connected by connecting a plurality of fixed resistors in series, and the variable resistor element or the signal control element in FIG. 5D is a continuous variable resistor;

FIG. 6A-6D show a control circuit diagram of the electrical switch unit in the first embodiment, where the variable resistor element shown in FIG. 6A is a continuous variable resistor, and the signal control element is an NC/NO switching circuit; both the variable resistor element and the signal control element shown in FIG. 6B are the continuous variable resistors; the variable resistor element shown in FIG. 6C is connected by connecting a plurality of fixed resistors in series, and the signal control element is an NC/NO switching unit; and both the variable resistor element and the signal control element shown in FIG. 6D are connected by connecting a plurality of fixed resistors in series;

FIGS. 7A-7F show a voltage change diagram of the control circuit shown in FIG. 6A, where FIG. 7A shows that a first region is continuously changed from a low level to a high level, and a second region is switched from a low level to a high level; FIG. 7B shows that the first region is continuously changed from the high level to the low level, and the second region is switched from the low level to the high level; FIG. 7C shows that the first region is continuously changed from the low level to the high level, and the second region is switched from the high level to the low level; FIG. 7D shows that the first region is continuously changed from the high level to the low level, and the second region is switched from the high level to the low level; FIG. 7E shows that the first region is continuously changed from the low level to the high level, and the second region is switched from the low level to the high level and is switched from the high level to the low level as well; and FIG. 7F shows that the first region is continuously changed from the high level to the low level, and the second region is switched from the low level to the high level and is switched from the high level to the low level as well;

FIG. 8A-8B show a voltage change diagram of the control circuit shown in FIG. 6B, where FIG. 8A shows that the first region is continuously changed from the low level to the high level, and the second region is continuously changed from the high level to the low level; and FIG. 8B shows that the first region is continuously changed from the high level to the low level, and the second region is continuously changed from the low level to the high level;

FIGS. 9A-9F show a voltage change diagram of the control circuit shown in FIG. 60, where FIG. 9A shows that the first region is changed from the low level to the high level step by step, and the second region is switched from the low level to the high level; FIG. 9B shows that the first region is changed from the high level to the low level step by step, and the second region is switched from the low level to the high level; FIG. 9C shows that the first region is changed from the low level to the high level step by step, and the second region is switched from the high level to the low level; FIG. 9D shows that the first region is changed from the high level to the low level step by step, and the second region is switched from the high level to the low level; FIG. 9E shows that the first region is changed from the low level to the high level step by step, and the second region is switched from the low level to the high level and is switched from the high level to the low level as well; and FIG. 9F shows that the first region is changed from the high level to the low level step by step, and the second region is switched from the low level to the high level and is switched from the high level to the low level as well;

FIG. 10A-10B show a voltage change diagram of the control circuit shown in FIG. 6D, where FIG. 10A shows that the first region is changed from the low level to the high level step by step, and the second region is changed from the high level to the low level step by step; and FIG. 10B shows that the first region is changed from the high level to the low level step by step, and the second region is changed from the low level to the high level step by step;

FIGS. 11A-11B show a perspective view of an operating sequence of a signaling module in a second embodiment, where a rolling element is connected with the second film contact surface in a rolling manner, and thus, the rolling element promotes a first conducting layer on the first film contact surface to be in contact with a contact surface of a variable resistor element, and where the rolling element in FIG. 11A is at the ON position, and the rolling element in FIG. 11B is at the OFF position;

FIGS. 11C-11F respectively show an exploded view and an assembly view of the signaling module in the second embodiment at the ON and OFF positions, where the signaling module includes the rolling element, a film, spacer elements, the contact surface of the variable resistor element, and where the rolling element in FIG. 11C and FIG. 11E is at the ON position, and the rolling element in FIG. 11D and FIG. 11E is at the OFF position;

FIGS. 12A-12D show a side view of the signaling module in the second embodiment, where, when the rolling element rolls on the second film contact surface, a first rolling portion of the rolling element promotes the first conducting layer to form contact with the contact surface of the variable resistor element, and where FIG. 12A and FIG. 12C show that one end of the first conducting layer is in crimp connection to a circuit board through a contact spring, the variable resistor element in FIG. 12A is connected by connecting a plurality of fixed resistors in series, and the variable resistor element in FIG. 12C is a continuous variable resistor; FIG. 12B and FIG. 12D show that one end of the first conducting layer is bonded to the circuit board through a conducting bonding layer, the variable resistor element in FIG. 12B is connected by connecting a plurality of fixed resistors in series, and the variable resistor element in FIG. 5D is a continuous variable resistor;

FIG. 13A-13B show a control circuit diagram of the electrical switch unit in the second embodiment, where the variable resistor element shown in FIG. 13A is a continuous variable resistor, and the variable resistor element shown in FIG. 13B is connected by connecting a plurality of fixed resistors in series;

FIGS. 14A-14B show a voltage change diagram of the control circuit shown in FIG. 13A, where FIG. 14A shows that the first region is continuously changed from the low level to the high level, and FIG. 14B shows that the first region is continuously changed from the high level to the low level; and

FIGS. 15A-15B show a voltage change diagram of the control circuit shown in FIG. 13B, where FIG. 15A shows that the first region is changed from the low level to the high level step by step, and FIG. 15B shows that the first region is changed from the high level to the low level step by step.

### DETAILED DESCRIPTION OF THE DRAWINGS AND THE PRESENTLY PREFERRED EMBODIMENTS

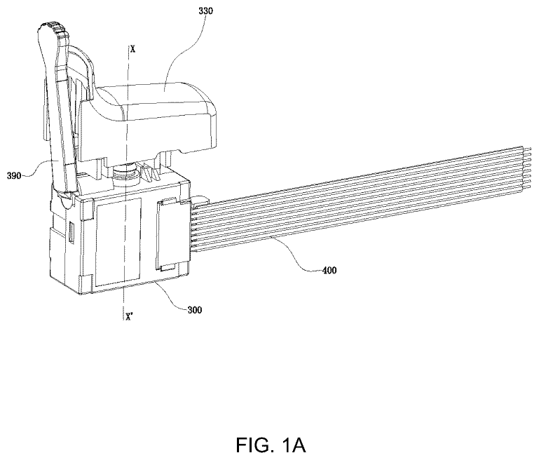

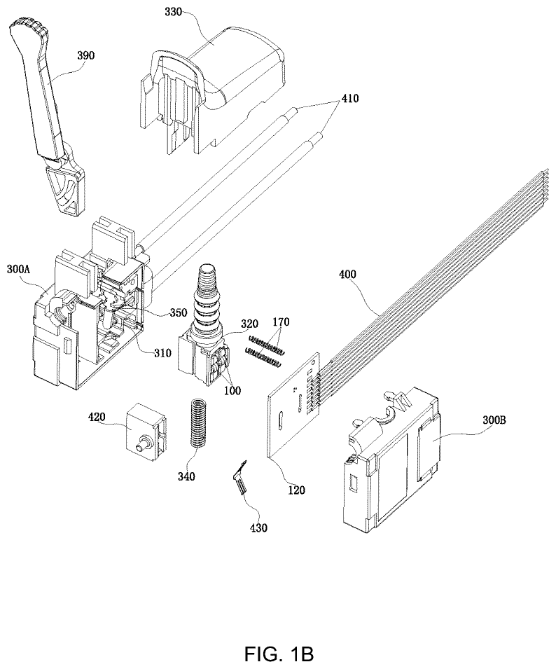

Preferred embodiments of the present invention will be described now with reference to FIGS. 1-15. The embodiments of the present invention are described herein for use associated with an electric tool. The electric tool can include, for example, a manually operable electric drill, an electric polishing machine, an electric sanding machine, an electric saw, an electric rotary driving tool, and the like. It will be clarified and understood that although the embodiments are described for use associated with the electric tool, this is merely for the convenience of describing the functionality, and alternative embodiments of the present invention can, of course, be used in any other type electrical devices such as an electric garden tool. It shall also be clarified that although the electric tool embodiments described herein relate to variable speed electric tools for the purpose of description, the alternative embodiments of the present invention can also be applied to use associated with non-variable speed electric tools.

The electric tool includes a brushed or brushless DC motor, where the brushless DC motor includes a rotor and a stator, and the stator is used for supplying a magnetic field that drives the rotor. The rotor of the brushless DC motor includes a plurality of output shafts supported by a bearing to provide an output torque and is encompassed by a fixed magnet that generates the magnetic field. The stator is installed around the rotor, and there is an air gap between the stator and the rotor. A stator winding is located in the air gap, is arranged parallel to the output shaft of the rotor, and can be usually connected as a triangular structure or a three-phase star connection structure. When a current flows through the stator winding, the current generated in the stator winding generates the magnetic field, the magnetic field is coupled with the rotor, and the rotor is “dragged” as the magnetic field surrounds it. The magnetic field generated by the fixed magnet in a rotor assembly tends to make it be aligned with the magnetic field generated by the stator, so that the rotor will experience a rotary movement. Therefore, by controlling the time sequence of the stator winding and electrifying sequentially, the rotary movement of a rotor shaft can be controlled to be set at any expected operating speed and in any expected direction, as described in further detail below.

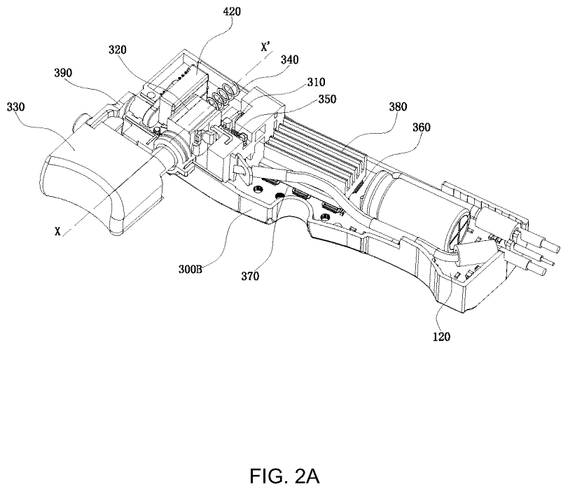

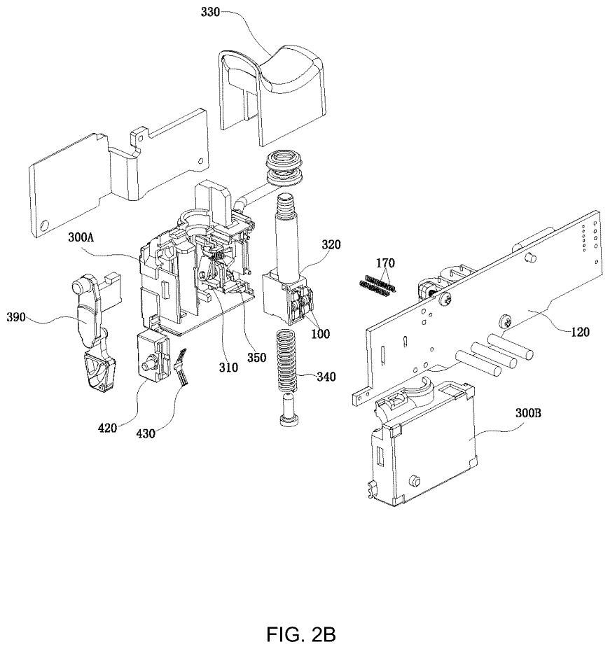

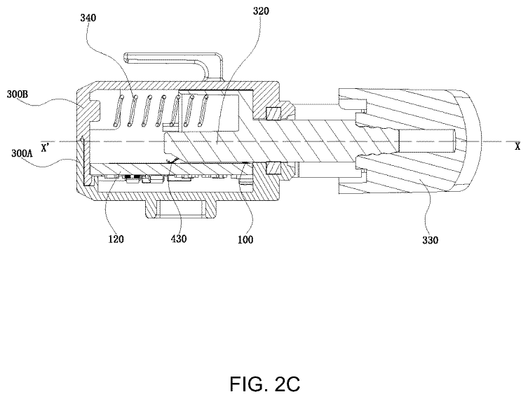

FIGS. 1-10 and FIGS. 11-15 show a first embodiment and a second embodiment of an electrical switch unit of the present invention. Each of the embodiments includes the electrical switch unit, where the electrical switch unit includes a shell 300; the shell 300 includes a bottom shell 300A and a surface cover 300B; the bottom shell 300A and the surface cover 300B can be connected together in a snap-fit or threaded manner, so as to substantially close at least some parts in parts of a signaling module. The shell 300 accommodates a pair of electrical switch contacts 310 and an actuator 320 operably connected to at least one of the pair of electrical switch contacts 310. The formed plastic shell 300 approaching a handle of an electric tool is installed on a main body of the electric tool. The electrical switch contacts 310 are arranged in series in a circuit between a brushed or brushless DC motor and a DC power supply (for example, a battery pack) of the electric tool. As shown in FIGS. 1A-1B and FIGS. 2A-2C, by pressing a trigger 330 with a finger of a user, the actuator 320 moves from an OFF position to an ON position inward along a moving axis (X-X′) relative to an opening in the shell 300. When the finger of the user releases the trigger 330, a reset spring 340 promotes the actuator 320 to move from the ON position to the OFF position inward along the moving axis X-X′ relative to the opening in the shell 300. The actuator 320 is operably connected to the electrical switch contacts 310, so that in response to the movement of the actuator 320 to the ON position, the electrical switch contacts 310 form a closed circuit arrangement, and thus, power from the DC power supply can be supplied to the brushed or brushless DC motor via the pair of electrical switch contacts 310. On the contrary, in response to promoting the actuator 320 to be at the OFF position, the pair of electrical switch contacts 310 is arranged in an open circuit structure, and thus, the DC power supply cannot supply power to the brushed or brushless DC motor via the pair of electrical switch contacts 310. Specifically, the pair of electrical switch contacts 310 includes a contact terminal and a fixed terminal. When the trigger 330 is not pressed, one end of the contact terminal is arranged opposite to the fixed terminal and the other end of the contact terminal abuts against a side surface of the actuator 320, and in this case, the contact terminal and the fixed terminal are disconnected; when the trigger 330 is pressed, the other end of the contact terminal is separated from the side surface of the actuator 320, a tension spring 350 pulls the contact terminal to the fixed terminal, and the contact terminal and the fixed terminal are connected and conducted; and after the trigger 330 is released, the other end of the contact terminal further abuts against the side surface of the actuator 320, and in this case, the contact terminal and the fixed terminal are disconnected.

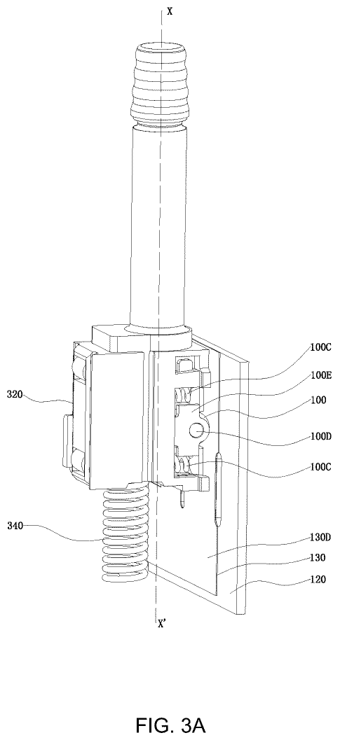

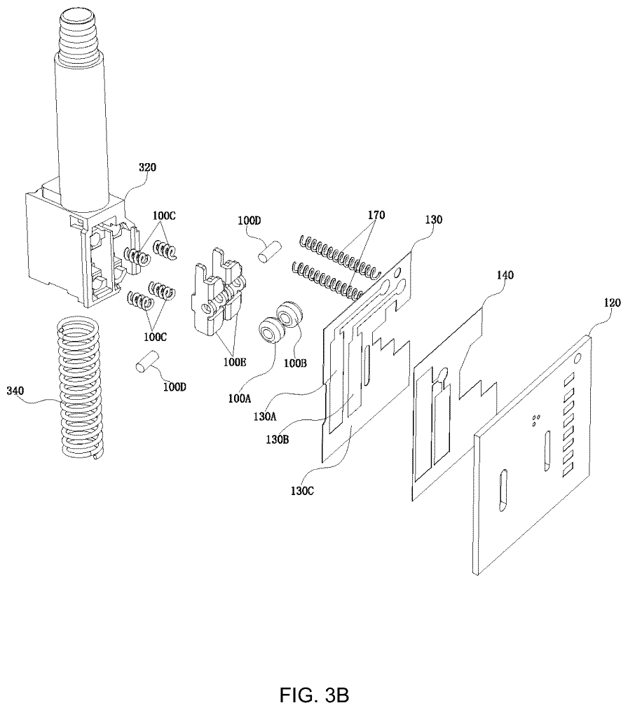

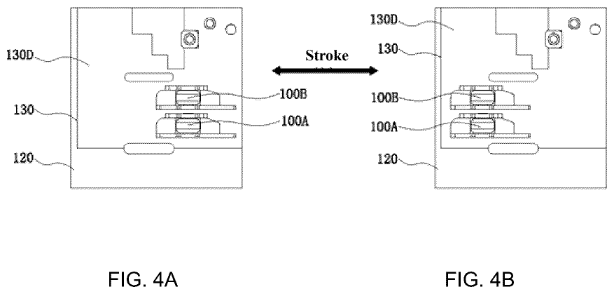

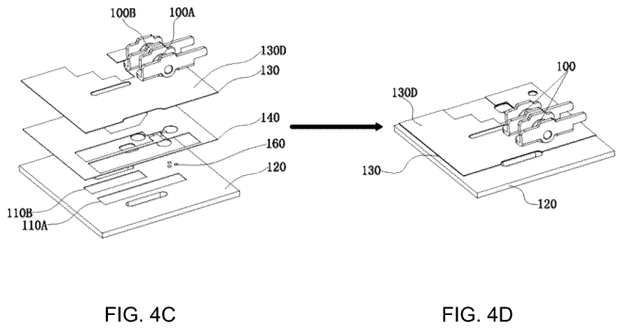

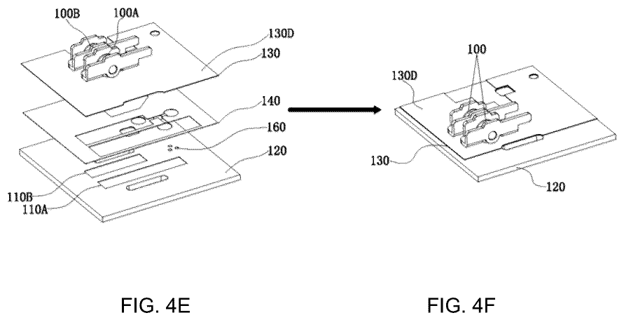

As shown in FIGS. 3A-3B and FIG. 4, depending on the magnitude of a force applied by the finger of the user to the trigger 330, the actuator 320 can move within a position in a certain range along the moving axis X-X′, and depending on linear movement of the actuator 320 along the moving axis X-X′, the brushed or brushless DC motor is configured to be operated at a variable operating speed. Specifically, the actuator 320 is connected to the signaling module arranged in the shell 300, where the signaling module includes a signaling circuit. The signaling circuit is used for sensing the linear movement of the actuator 320 relative to a reference position and outputting a signaling module signal. The signaling module signal indicates the movement or position of the sensed actuator 320 and thus, indicates an operating speed of the motor excepted by the user.

As shown in FIGS. 2A-2C, a power module 360 is provided. The power module 360 includes at least one solid state power switch device which is an MOSFET in the embodiment. The solid state power switch devices are connected in series to corresponding stator windings of the brushed or brushless DC motor via motor cables, respectively. These MOSFETs are configured to make the current selectively and controllably applied to inputs of the corresponding stator windings of the brushed or brushless DC motor. The stator windings are actuated sequentially according to controlled timing and sequence with reference to the control module, and a permanent magnet of the rotor continuously follows a propelling magnetic field generated by the stator windings.

As shown in FIGS. 2A-2C, the control module 370 including a motor control circuit receives the signaling module signal from the signaling module and outputs an electrical signal of the control module 370 operated by driving the power module 360 in response to the received signaling module signal, where the power module 360 includes a plurality of MOSFETs connected to corresponding input terminals of the stator windings of the brushless DC motor. The control module 370 includes a microcontroller, where the microcontroller is programmed to output the signal of the control module 370. The signal of the control module 370 drives the plurality of MOSFETs of the power module 360 to electrify the stator windings corresponding to the MOSFETs according to preset timing and sequence, so that the brushless DC motor operates in a predetermined mode (i.e., speed, direction, and torque) corresponding to the movement of the actuator 320 indicated by the signaling module signal. The speed and torque of the brushed or brushless DC motor depend on the magnitude of the power that can be supplied to the stator windings via corresponding input MOSFETs of the stator windings. In these embodiments, the magnitude of the power supplied to the stator windings can be changed controllably by using a pulse width modulation technology. Therefore, an output of a timing signal generator (for example, a “555” circuit) serves as an input of a grid electrode of each of the MOSFETs to properly achieve high-speed on-off of the MOSFETs. Therefore, the power obtained by switching the MOSFETs to the stator windings provides the speed and torque of an expected magnitude generated by the brushed or brushless DC motor. A signal of the timing signal generator can thus serve as the signal of the control module 370 that controls the operations of the MOSFETs. In some embodiments, the control module 370 can further include a voltage regulation and protection circuit to regulate an input voltage from the DC power supply to each of the MOSFETS.

In the embodiments of the present invention, the control module 370 and the electrical switch contacts 310 and/or the signaling module are integrally and electrically formed together, so that a relatively direct electrical connection between the electrical switch contacts 310 and/or the signaling module and the control module 370 is allowed. On this point, the control module 370 and the signaling module can be usually formed on a single circuit board 120 and are electrically connected directly as they can be integrally formed in the circuit board itself. Specifically, the electrical connection among the electrical switch contacts 310, the signaling module, and the control module 370 is provided by conducting pins, conducting paths, conducting buses and the like that may be integrally embedded into the circuit board 120 itself. The electrical switch unit shown in FIGS. 2A-2C is an integral switch (integrated switch) with a switch module. Besides the signaling module, the control module 370 and the power module 360 are further integrated into the circuit board 120 thereof. By integrating a signal switch and the control module 370 that are originally separated into an integrated switch, the installation is facilitated, and the installation time is shortened. In some embodiments, the signaling module and the control module 370 can further be formed on physically separated circuit boards. The physically separated circuit boards are properly arranged relative to each other to allow the relatively direct and integrated electrical connection between the control module 370 and the electrical switch contacts 310 and/or the signaling module. The electrical switch unit shown in FIGS. 1A-1B is a non-integral switch (the signal switch) without the switch module. The electrical switch unit has the signaling module but does not have the control module 370 and the power module 360, and can be connected to the circuit board integrated with the control module 370 and the power module 360 through a flat cable 400 and a cable 410.

In the embodiments of the present invention, the power module 360, and the control module 370 and the signaling module of the electrical switch unit are integrally formed on the single circuit board 120 together. As shown in FIGS. 2A-2B, because the MOSFETs arranged on the power module 360 tend to generate a relatively large amount of heat, one or more heat dispersion and/or dissipation elements such as heat dissipation fins 380 are installed on the surface of the power module 360 to disperse and/or dissipate heat energy from the MOSFETs to surrounding ambient air. Thanks to the usual topological irregular surfaces of the MOSFETs and other parts on the power module 360, a heat conducting pad, heat conducting paste or a heat conducting compound can serve as a middle heat transfer layer between the surface of each of the MOSFETs and the heat dissipation fin 380 and the like to achieve a more effective heat connection with the MOSFETs. In some embodiments, the signaling module and the control module 370 can be integrally formed on a single circuit board, and the power module 360 is formed on another physically separated circuit board. The two circuit boards can be installed relative to each other in a structure where the two circuit boards are spaced parallelly or can be installed relative to each other in a structure where the two circuit boards are relatively perpendicular, so that heat energy from the MOSFETs installed on the power module 360 can be spaced from the circuit board with the control module 370 and the signaling module, so that probable heat damage caused by these modules is alleviated.

In the embodiments of the present invention, further provided is a direction control assembly, as shown in FIGS. 1A-1B and 2A-2C, including a reversing bar 390 rotatably connected to the shell 300, a slide block part 420 operably connected to another end of the reversing bar 390, and a reversing track structure arranged between the slide block part 420 and the circuit board 120 for controlling diversion of the brushed or brushless DC motor. The slide block part 420 is arranged on one side of a rotating plane of the reversing bar 390, and the slide block part 420 driven by the reversing bar 390 can be connected to the reversing track structure in a reciprocating manner, where the reversing track structure includes a reversing brush blade 430 facing the circuit board 120 and arranged on the slide block part 420, and a first conducting strip, a second conducting strip, and a third conducting strip sequentially arranged at an interval along a motion path of the slide block part 420. One end of the reversing brush blade 430 is slidably connected to the first conducting strip all the time and the other end thereof slides between the second conducting strip and the third conducting strip in a switched manner. It can be known from the above structure that the reversing bar 390 drives the reversing brush blade 430 on the slide block part 420 to slip on the reversing track structure of the circuit board 120 during rotation and generates a signal that controls the diversion of the brushed or brushless DC motor. The control module 370 receives and processes the control signal. A specific operating process of the direction control assembly is as follows: when the reversing bar 390 is in the middle, one end of the reversing brush blade 430 is connected to the first conducting strip all the time and the other end thereof is located between the second conducting strip and the second conducting strip, and in this case, the switch is not electrified and the signal of the brushed or brushless DC motor is not generated; when the reversing bar 390 rotates clockwise, the reversing brush blade 430 is respectively connected to the first conducting strip and the third conducting strip, and in this case, when the switch is electrified, a forward signal of the brushed or brushless DC motor is generated; and when the reversing bar 390 rotates anticlockwise, the reversing brush blade 430 is respectively connected to the first conducting strip and the second conducting strip, and in this case, when the switch is electrified, a reverse signal of the brushed or brushless DC motor is generated, so that reversing control of the brushed or brushless DC motor is achieved.

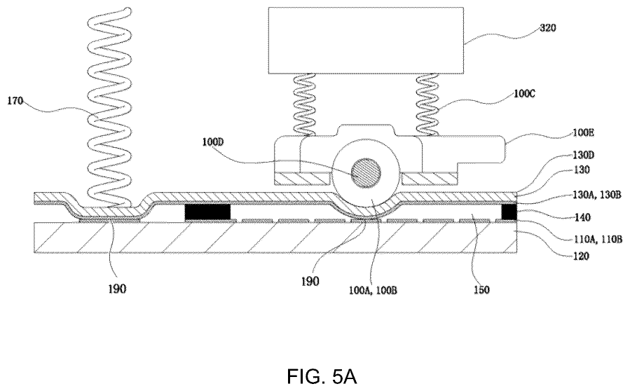

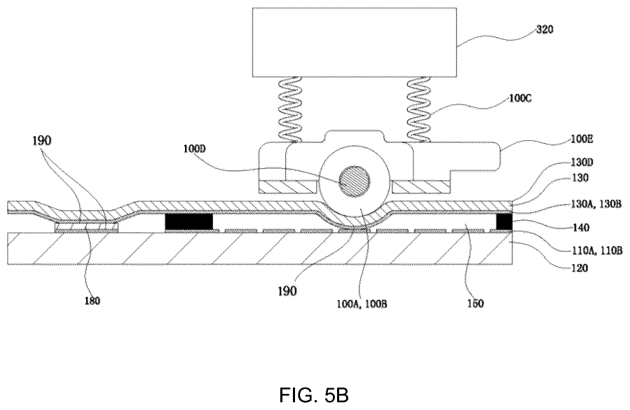

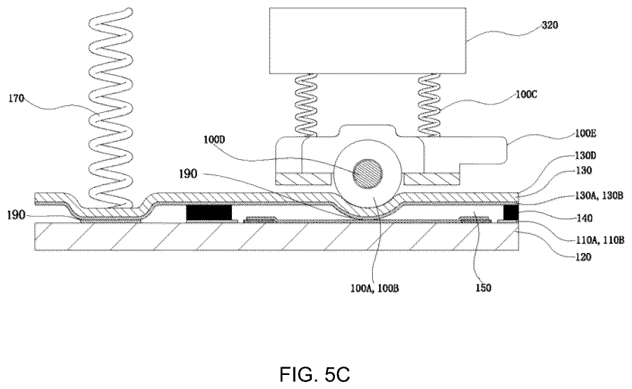

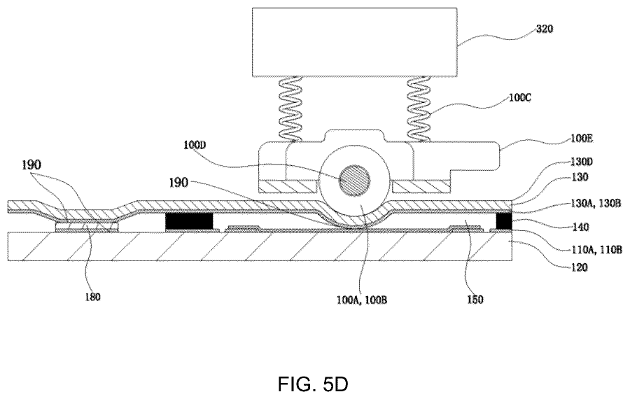

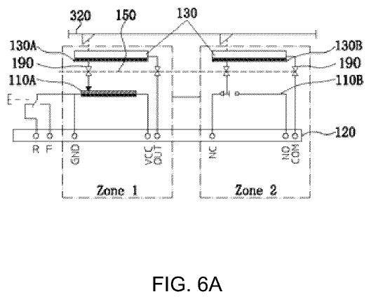

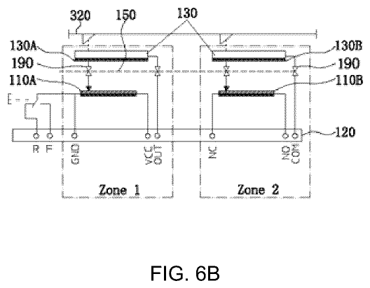

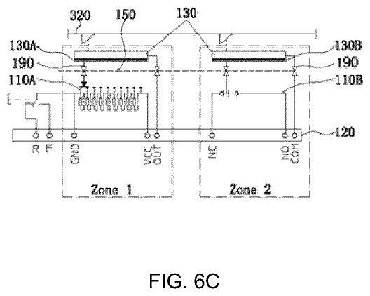

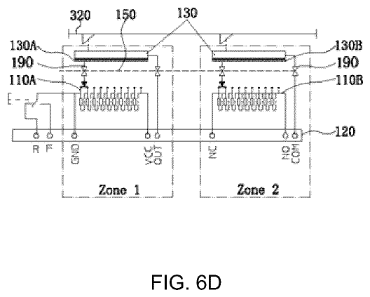

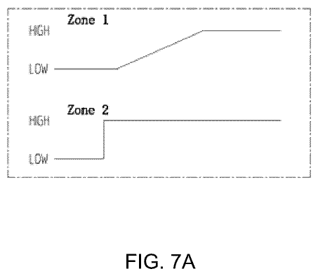

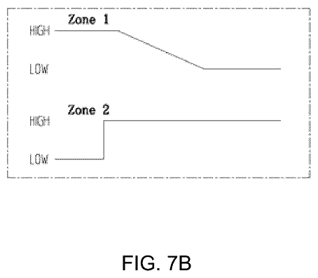

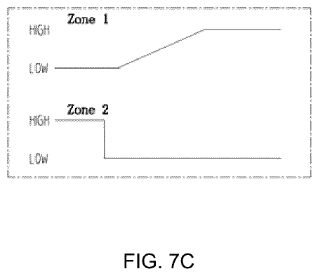

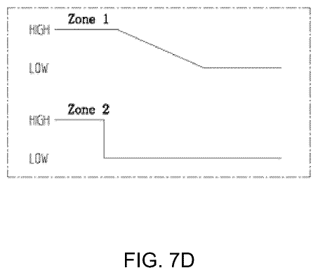

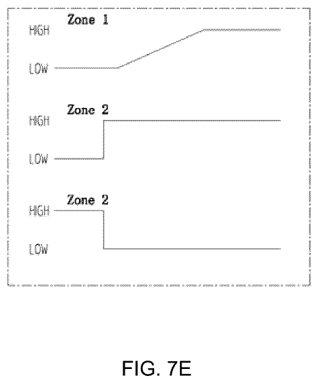

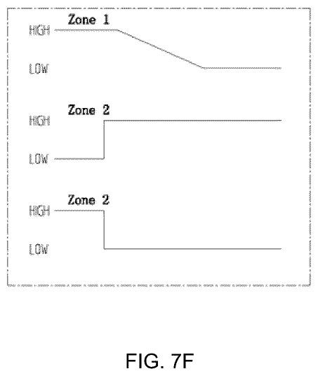

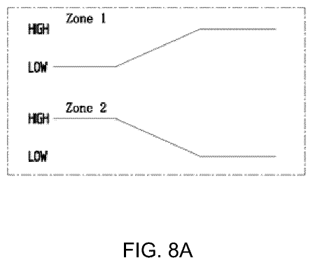

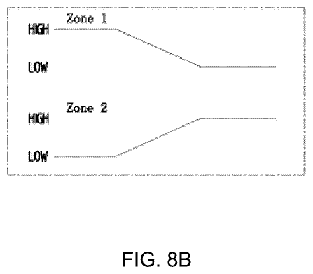

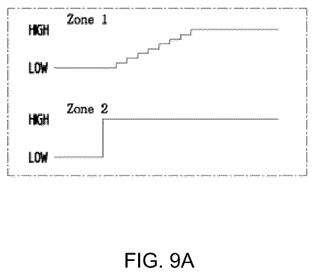

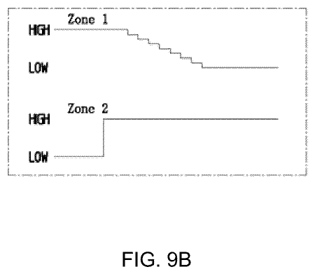

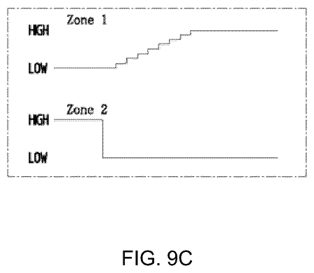

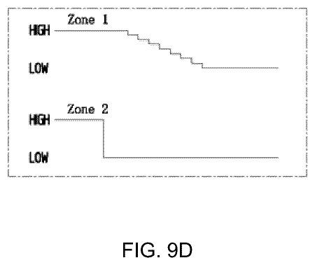

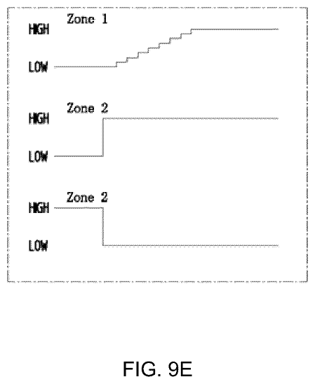

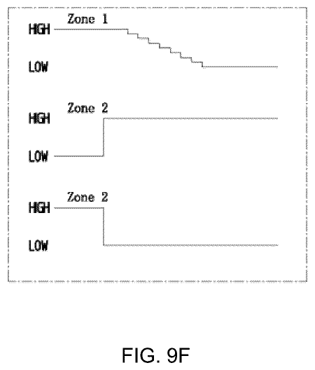

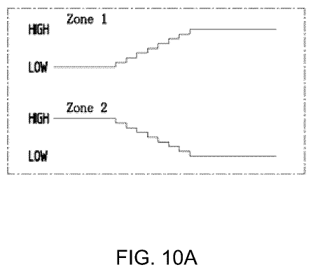

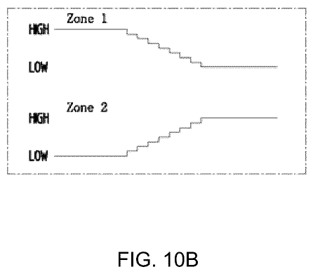

In the embodiment, the signaling circuit is at least partially formed on the circuit board 120. Specifically, as shown in FIGS. 4A-4F and 5A-5D, the circuit board 120 includes a first region provided with a variable resistor element and a second region having a signal control element, the variable resistor element having a contact surface 110A of the variable resistor element and the signal control element having a contact surface 110B of the signal control element. In the embodiments of the present invention, the variable resistor element located in the first region can be a continuous variable resistor or can be connected by connecting a plurality of fixed resistors in series; and the signal control element located in the second region is a continuous variable resistor or can be connected by connecting the plurality of fixed resistors in series, or is a NC/NO switching circuit. Optionally, when the variable resistor element is the continuous variable resistor and the signal control element is the NC/NO switching circuit, a control circuit diagram thereof is shown in FIG. 6A, and a voltage change diagram thereof is shown in FIGS. 7A-7F; when both the variable resistor element and the signal control element are the continuous variable resistors, a control circuit diagram thereof is shown in FIG. 6B, and a voltage change diagram thereof is shown in FIGS. 8A-8B; when the variable resistor element is connected by connecting a plurality of fixed resistors in series and the signal control element is the NC/NO switching circuit, a control circuit diagram thereof is shown in FIG. 6C, and a voltage change diagram thereof is shown in FIGS. 9A-9F; and when both the variable resistor element and the signal control element are connected by connecting a plurality of fixed resistors in series, a control circuit diagram thereof is shown in FIG. 6D, and a voltage change diagram thereof is shown in FIGS. 10A-10B. The control circuit is used for receiving signals of the variable resistor element and the signal control element and outputting the signal of the control module 370 in response to the received signal of the signaling module. Specifically, as shown in FIGS. 6A-6D, one end of the variable resistor element in the first region is connected to a positive electrode of a regulated power supply and the other end thereof is connected to a negative electrode of the regulated power supply. One end of the signal control element in the second region is connected to a normally closed terminal and the other end thereof is connected to a normally opened terminal. A connecting end between the variable resistor element and the negative electrode of the power supply is also electrically connected to the reversing track structure of the direction control assembly to achieve reversing control of the brushed or brushless DC motor. A bottom surface of the first conducting layer 130A is in abutting connection to the contact surface 110A of the variable resistor element, one end of the first conducting layer 130A is connected to an output end, a bottom surface of the second conducting layer 130B is in abutting connection to the contact surface 110B of the signal control element, and one end of the second conducting layer 130B is connected to a common terminal.

As an example, when the variable resistor element or the signal control element is connected by connecting a plurality of fixed resistors, the variable resistor element or the signal control element can include, for example, a group of nine resistors, which can be configured to be connected in series between the power supply of the electrical device and the input pins of the control module 370. Eight conducting path lines stretch out from eight middle nodes among nine resistors connected in series. The eight conducting path lines are printed on the surface of the circuit board 120 to form an array of independent discrete path lines on the contact surface 110A of the variable resistor element or the contact surface 110B of the signal control element. It can thus be understood that by electrically bridging different path lines in the contact surface 110A of the variable resistor element and the contact surface 110B of the signal control element to the first conducting layer 130A and the second conducting layer 130B, respectively, a variable voltage can be selectively applied to the input pins of the control module 370. In a specific embodiment of the present invention, the contact surface 110A of the variable resistor element and the contact surface 110B of the signal control element are arranged in the same plane in parallel, and the first region and the second region are arranged to be physically separated and spaced; for example, two independent elongated stripes are printed on the surface of the circuit board 120, as shown in FIGS. 4A-4F.

Referring to FIGS. 5A-5D, the signaling module further includes a relatively thin and flexible film 130, and can be, for example, formed by a polymer, a copolymer or a polymer composite material. The film 130 includes a first film contact surface 130C on the lower surface of the film 130 and a second film contact surface 130D on the upper surface of the film 130. The first film contact surface 130C on the lower surface of the film 130 has the first conducting layer 130A and the second conducting layer 130B. The first conducting layer 130A and the second conducting layer 130B are formed by a conducting material printed on the first film contact surface 130C of the film 130. The film 130 is installed on the circuit board 120 in a bonded manner, so that the first film contact surface 130C of the film 130 faces the contact surface 110A of the variable resistor element and the contact surface 110B of the signal control element and is spaced from the contact surface 110A of the variable resistor element and the contact surface 110B of the signal control element through a spacer element 140, and thus, space 150 is formed therebetween. A periphery of the spacer element 140 around the film 130 is located among the first conducting layer 130A and the second conducting layer 130B, and the contact surface 110A of the variable resistor element and the contact surface 110B of the signal control element. The spacer element 140 can further include a polymer, a copolymer or a polymer composite material. One end of the spacer element is attached to the first conducting layer 130A and the second conducting layer 130B of the first film contact surface 1300 in a bonded manner and the other end thereof is attached to the contact surface 110A of the variable resistor element and the contact surface 110B of the signal control element in a bonded manner. By default, the first conducting layer 130A and the second conducting layer 130B are biased to positions spaced relative to the contact surface 110A of the variable resistor element and the contact surface 110B of the signal control element. The biasing can be achieved by configuring a structure of the film 130 itself and/or using an external biasing element such as the spacer element 140. Whether the user presses the trigger 330 or not, the first conducting layer 130A and the second conducting layer 130B are respectively connected and conducted to the contact surface 110A of the variable resistor element and the contact surface 110B of the signal control element at a certain contact point.

In the embodiment, one end of each of the first conducting layer 130A and the second conducting layer 130B of the first film contact surface 130C is electrically connected to the circuit board 120, and for example, can be connected through a wire. In the embodiment, one end of each of the first conducting layer 130A and the second conducting layer 130B of the first film contact surface 130C of the film 130 is in contact connection with the circuit board 120. Optionally, one end of each of the first conducting layer 130A and the second conducting layer 130B of the first film contact surface 130C can be in crimp connection to the circuit board 120 through each of two contact springs 170 to achieve the electric connection; under the pressure of each of the contact springs 170, one end of each of the first conducting layer 130A and the second conducting layer 130B of the first film contact surface 130C can be promoted to be in contact with the circuit board 120 (contact position 190), as shown in FIGS. 5A and 5C; one end of each of the first conducting layer 130A and the second conducting layer 130B of the first film contact surface 130C of the film 130 can be bonded to the circuit board 120 through a conducting bonding layer 180 (for example, conducting glue, a conducting adhesive tape or glue such as an epoxy adhesive, a polyurethane adhesive, and an acrylic adhesive) to achieve the electric connection (contact position 190), as shown in FIGS. 5B and 5D; and in some embodiments, one end of each of the first conducting layer 130A and the second conducting layer 130B of the first film contact surface 130C of the film 130 can be welded to the circuit board 120 through a silver solder and the like to achieve the electric connection.

In the embodiment, the moving component is operably connected to the actuator 320 and is configured to move along the second film contact surface 130D of the film 130 in response to the moving component. The moving component can be a sliding part such as a slide block and a slip sheet. In the embodiments of the present invention, the moving component is a rolling part 100 such as a roller. As the rolling part 100 moves in a rolling manner on the second film contact surface 130D of the film 130, friction and wear among the rolling part 100, the film 130, and the contact surface 110A of the variable resistor element and the contact surface 110B of the signal control element can be reduced, so that the reliability and stability of operations of the electrical switch unit can be maintained within a longer duration of use. As shown in FIGS. 4A-4F, the rolling part 100 includes a first rolling portion 100A and a second rolling portion 100B. With the movement of the rolling part 100 along the second film contact surface 130D of the film 130, thanks to a vertical force caused by the rolling part 100 pushing the second film contact surface 130D of the film 130, the first conducting layer 130A and the second conducting layer 130B of the first film contact surface 130C are promoted to form contact with the contact surface 110A of the variable resistor element and the contact surface 110B of the signal control element at a plurality of contact point structures, respectively. In each of the plurality of contact point structures, the contact points are formed, so that the first rolling portion 100A of the rolling part 100 forces a part of the first conducting layer 130A to form contact with the contact surface 110A of the variable resistor element, and the second rolling portion 100B forces a part of the second conducting layer 130B to form contact with the contact surface 110B of the signal control element. Therefore, as the rolling part 100 rolls along the second film contact surface 130D of the film 130, the first conducting layer 130A and the second conducting layer 130B can be electrically bridged with the contact surface 110A of the variable resistor element and the contact surface 110B of the signal control element selectively, and effective resistance of the variable resistor element and the signal control element can be changed correspondingly in a controlled manner, resulting in that the changed voltage signal is applied to the input end of the control module 370. The variable voltage input indicates the movement of the actuator 320, and the control module 370 is programmed to control the operations of the brushed or brushless DC motor with reference to the variable voltage signal. Besides, the signal control element can also be the NC/NO switching circuit for signal control. The circuit of the signal control element is configured to switching signals in response to promoting the second conducting layer to form contact with the contact surface of the signal control element in one of the plurality of contact point structures. The selectable signal includes, but is not limited to, an on/off signal, different signals, and the like.

In the embodiment, as shown in FIGS. 3A-3B, the rolling part 100 can be biased by a compression spring 100C in a direction substantially perpendicular to the moving direction of the rolling part 100. Besides, the rolling part 100 can be installed on a bracket 100E through a pin shaft 100D, the bracket 100E is installed in a slot of the actuator 320 close to one side of the circuit board 120, and the rolling part 100 can be in spherical, ellipsoidal, and cylindrical shapes or any shape applicable to rolling. The structures of the first rolling portion 100A and the second rolling portion 100B of the rolling part 100 can be selected to match the structures of the contact surface 110A of the variable resistor element and the contact surface 110B of the signal control element. In the embodiment, the first rolling portion 100A and the second rolling portion 100B are independently separated and spaced from each other.

In the embodiment, an exhaust hole 160 that passes through upper and lower surfaces of the circuit board 120 is formed at a position of the circuit board 120 corresponding to the space 150. Optionally, the spacer element 140 is provided with a round hole at a position corresponding to the exhaust hole 160 in the circuit board 120. The round hole is respectively connected to the space 150 corresponding to the contact surface 110A of the variable resistor element and the contact surface 110B of the signal control element through a first strip-shaped hole and a second strip-shaped hole. When the rolling part 100 moves in a rolling manner along the second film contact surface 130D of the film, the space 150 surrounded by the spacer element 140 is compressed, and the exhaust hole 160 is used for exhausting when the space 150 is compressed.

Advantageously, in the signaling module of the electrical switch unit, the sizes of the film 130, the spacer element 140, and the circuit board 120 can be reduced by respectively spacing the first conducting layer 130A and the second conducting layer 130B of the first film contact surface 130C from the contact surface 110A of the variable resistor element and the contact surface 110B of the signal control element through the spacer element 140, so that the space occupied by the actuator 320 and the electrical switch is reduced. Besides, the number of the moving components can also be reduced. Conventional two groups of moving components are decreased to one group of moving components, so that the material cost is lowered.

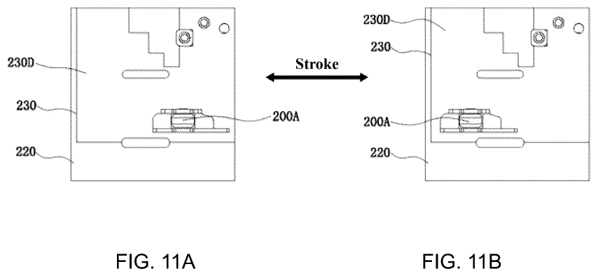

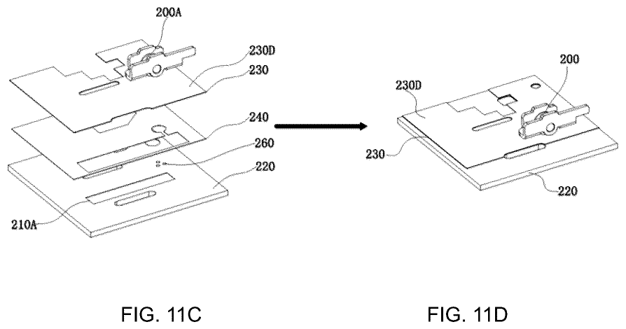

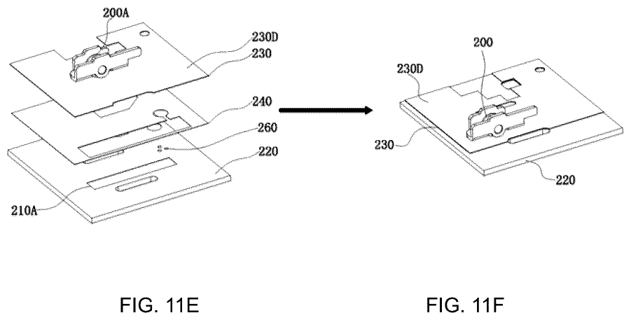

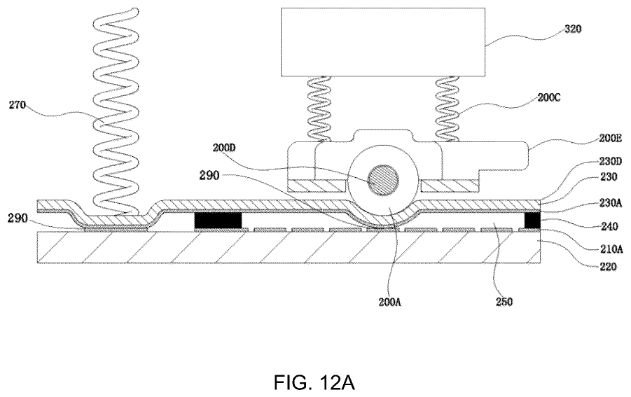

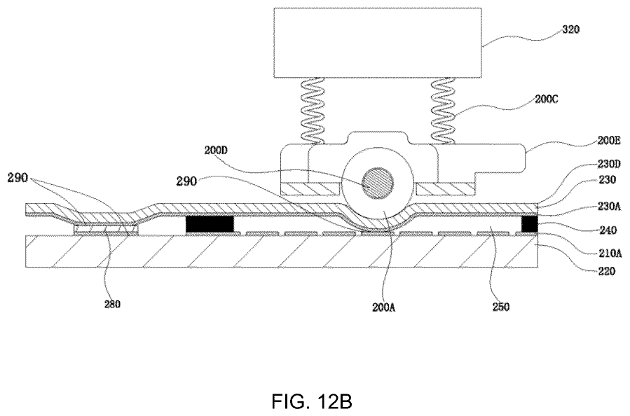

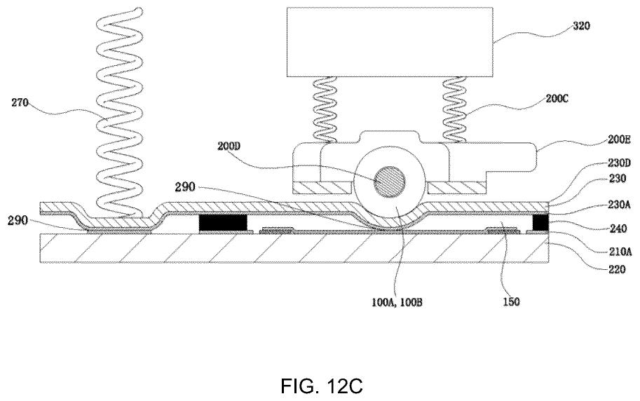

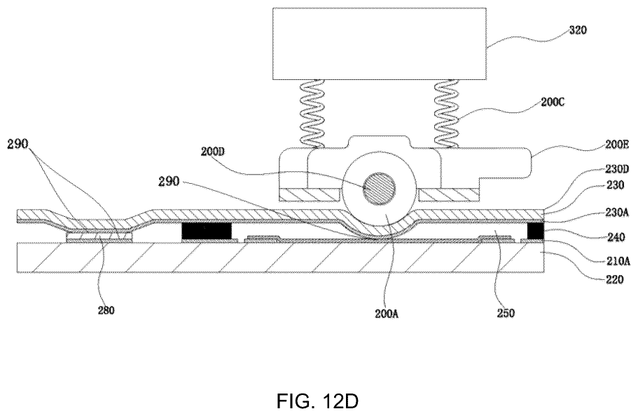

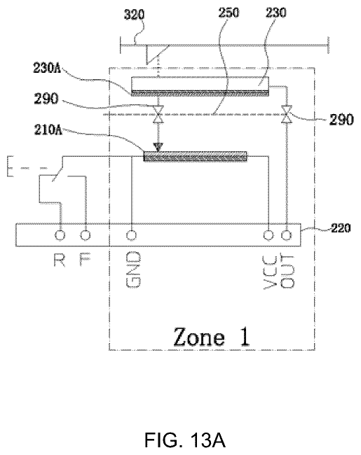

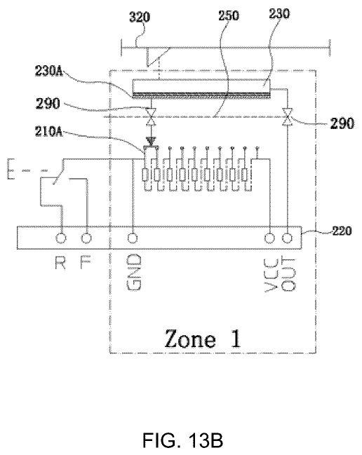

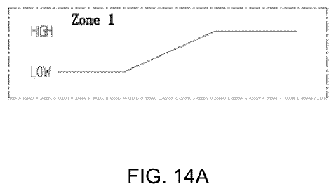

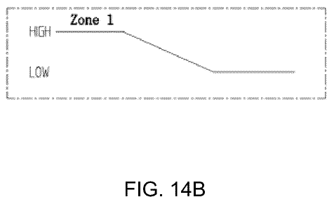

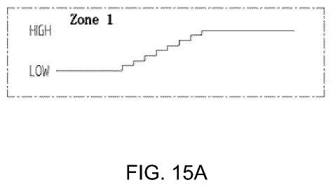

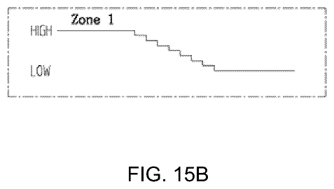

In the second embodiment, the signaling circuit is at least partially formed on the circuit board 220. Specifically, as shown in FIGS. 11A-11F and 12A-12D, the circuit board 220 includes a first region provided with a variable resistor element, the variable resistor element having a contact surface 210A of the variable resistor element. In the embodiment of the present invention, the variable resistor element located in the first region can be a continuous variable resistor or connected by connecting a plurality of fixed resistors in series. Optionally, when the variable resistor element is the continuous variable resistor, a control circuit diagram thereof is shown in FIG. 13A, and a voltage change diagram thereof is shown in FIG. 14; and when the variable resistor element is connected by connecting a plurality of fixed resistors, a control circuit diagram thereof is shown in FIG. 13B, and a voltage change diagram thereof is shown in FIG. 15. Specifically, as shown in FIGS. 13A-13B, one end of the variable resistor element in the first region is connected to a positive electrode of a power supply and the other end thereof is connected to a negative electrode of the power supply; and a connecting end between the variable resistor element and the negative electrode of the power supply is also electrically connected to the reversing track structure of the direction control assembly to achieve reversing control of the brushed or brushless DC motor. A bottom surface of the first conducting layer 130A is in abutting connection to the contact surface 210A of the variable resistor element, and one end of the first conducting layer 230A is connected to an output end.

As an example, when the variable resistor element is connected by connecting a plurality of fixed resistors, the variable resistor element can include, for example, a group of nine resistors, which can be configured to be connected in series between the power supply of the electrical device and the input pins of the control module 370. Eight conducting path lines stretch out from eight middle nodes among nine resistors connected in series. The eight conducting path lines are printed on the surface of the circuit board 220 to form an array of independent discrete path lines on the contact surface 210A of the variable resistor element. It can thus be understood that by electrically bridging different path lines in the contact surface 210A of the variable resistor element to the first conducting layer 230A, respectively, a variable voltage can be selectively applied to the input pins of the control module 370.

Referring to FIGS. 12A-12D, the signaling module further includes a relatively thin and flexible film 230, and can be, for example, formed by a polymer, a copolymer or a polymer composite material. The film 230 includes a first film contact surface 230C on the lower surface of the film 230 and a second film contact surface 230D on the upper surface of the film 230. The first film contact surface 230C on the lower surface of the film 230 has the first conducting layer 230A. The first conducting layer 230A is formed by a conducting material printed on the first film contact surface 230C of the film 230. The film 230 is installed on the circuit board 220 in a bonded manner, so that the first film contact surface 230C of the film 230 faces the contact surface 210A of the variable resistor element and is spaced from the contact surface 210A of the variable resistor element through a spacer element 240, and thus, space 250 is formed therebetween. A periphery of the spacer element 240 around the film 230 is located between the first conducting layer 230A and the contact surface 210A of the variable resistor element. The spacer element 240 can further include a polymer, a copolymer or a polymer composite material. One end of the spacer element is attached to the first conducting layer 230A of the first film contact surface 230C in a bonded manner and the other end thereof is attached to the contact surface 210A of the variable resistor element in a bonded manner. By default, the first conducting layer 230A is biased to a position spaced relative to the contact surface 210A of the variable resistor element. The biasing can be achieved by configuring a structure of the film 230 itself and/or using an external biasing element such as the spacer element 240. Whether the user presses the trigger 330 or not, the first conducting layer 230A is connected and conducted to the contact surface 210A of the variable resistor element at a certain contact point.

In the alternative embodiment, one end of the first conducting layer 230A of the first film contact surface 230C is electrically connected to the circuit board 220, and for example, can be connected through a wire. In the embodiment, one end of the first conducting layer 230A of the first film contact surface 230C of the film 230 is in contact connection with the circuit board 220. Optionally, one end of the first conducting layer 230A of the first film contact surface 230C can be in crimp connection to the circuit board 220 through a contact spring 270 to achieve the electric connection; under the pressure of the contact spring 270, one end of the first conducting layer 230A of the first film contact surface 230C can be promoted to be in contact with the circuit board 220 (contact position 290), as shown in FIGS. 12A and 12C; one end of the first conducting layer 230A of the first film contact surface 230C of the film 230 can be bonded to the circuit board 220 through a conducting bonding layer 280 (for example, conducting glue, a conducting adhesive tape or glue such as an epoxy adhesive, a polyurethane adhesive, and an acrylic adhesive) to achieve the electric connection (contact position 290), as shown in FIGS. 12B and 12D; and in some embodiments, one end of the first conducting layer 230A of the first film contact surface 230C of the film 230 can be welded to the circuit board 220 through a silver solder and the like to achieve the electric connection.

In the alternative embodiment, the moving component is operably connected to the actuator 320 and is configured to move along the second film contact surface 230D of the film 230 in response to the moving component. The moving component can be a sliding part such as a slide block and a slip sheet. In the embodiments of the present invention, the moving component is a rolling part 200 such as a roller. As the rolling part 200 moves in a rolling manner on the second film contact surface 230D of the film 230, friction and wear among the rolling part 200, the film 230, and the contact surface 210A of the variable resistor element can be reduced, so that the reliability and stability of operations of the electrical switch unit can be maintained within a longer duration of use. As shown in FIGS. 11A-11F, the rolling part 200 includes a first rolling portion 200A. With the movement of the rolling part 200 along the second film contact surface 230D of the film 230, thanks to a vertical force caused by the rolling part 200 pushing the second film contact surface 230D of the film 230, the first conducting layer 230A of the first film contact surface 230C is promoted to form contact with the contact surface 210A of the variable resistor element at a plurality of contact point structures, respectively. In each of the plurality of contact point structures, the contact points are formed, so that the first rolling portion 200A of the rolling part 200 forces a part of the first conducting layer 230A to form contact with the contact surface 210A of the variable resistor element. Therefore, as the rolling part 200 rolls along the second film contact surface 230D of the film 230, the first conducting layer 230A can be electrically bridged with the contact surface 210A of the variable resistor element selectively, and effective resistance of the variable resistor element can be changed correspondingly in a controlled manner, resulting in that the changed voltage signal is applied to the input end of the control module 370. The variable voltage input indicates the movement of the actuator 320, and the control module 370 is programmed to control the operations of the brushed or brushless DC motor with reference to the variable voltage signal.

In the alternative embodiment, the rolling part 200 can be biased by a compression spring 200C in a direction substantially perpendicular to the moving direction of the rolling part 200. Besides, the rolling part 200 can be installed on a bracket 200E through a pin shaft 200D, the bracket 200E is installed in a slot of the actuator 320 close to one side of the circuit board 120, and the rolling part 200 can be in spherical, ellipsoidal, and cylindrical shapes or any shape applicable to rolling.

In the alternative embodiment, an exhaust hole 260 that passes through upper and lower surfaces of the circuit board 220 is formed at a position of the circuit board 220 corresponding to the space 250. Optionally, the spacer element 240 is provided with a round hole at a position corresponding to the exhaust hole 260 in the circuit board 220. The round hole is connected to the space 250 corresponding to the contact surface 210A of the variable resistor element through a strip-shaped hole. When the rolling part 200 moves in a rolling manner along the second film contact surface 230D of the film, the space 250 surrounded by the spacer element 240 is compressed, and the exhaust hole 260 is used for exhausting when the space 250 is compressed.

Advantageously, in the signaling module of the electrical switch unit, the sizes of the film 230, the spacer element 240, and the circuit board 220 can be reduced by spacing the first conducting layer 230A of the first film contact surface 230C from the contact surface 210A of the variable resistor element through the spacer element 240, so that the space occupied by the actuator 320 and the electrical switch is reduced. Besides, the number of the moving components can also be reduced. Conventional two groups of moving components are decreased to one group of moving components, so that the material cost is lowered.

In the alternative embodiment of the present invention, it is possible to use the following arrangement. For example, the circuit board is alternatively manufactured on a flexible film material, and the rolling portion of the rolling part can be configured to promote the circuit board to form contact with the variable resistor in a mode contrary to that in the above embodiments.

Those skilled in the art will recognize that besides those specially described, the present invention described herein can further be changed and altered without departing from the scope of the present invention. These changes and alternations apparent to those skilled in the art all are regarded as falling into the spirit and scope of the present invention widely described above. It can be understood that the present invention includes all these changes and alternations. The present invention further includes all steps and features cited or indicated in the specification along or together and any and all combinations of any two or more steps or features.

Any prior art mentioned in the specification shall not be regarded as admitting or implying in any form that the prior art forms a part of common sense. CLAIMS

1. An electrical switch unit for an electrical device, the electrical switch unit being used for controlling an operation of a DC motor of the electrical device, wherein the electrical switch unit comprises:
a shell, wherein the shell accommodates an actuator movably installed in the shell, the actuator being configured to be capable of moving toward an ON position from an OFF position in a direction toward an interior of an opening in the shell along a moving axis and to be capable of moving toward the OFF position from the ON position in a direction toward an exterior of the opening in the shell along the moving axis in response to operations of a finger-operable trigger; and
a signaling module, wherein the signaling module is associated with the electrical switch unit and comprises a signaling circuit, the signaling circuit being used for sensing a movement of the actuator and outputting a signaling module signal that indicates the movement or position of the sensed actuator;
wherein the signaling module comprises:
a circuit board, wherein the circuit board comprises a first region provided with a variable resistor element, and the variable resistor element having a contact surface of the variable resistor element;
a film, wherein the film comprises a first film contact surface and a second film contact surface, the first film contact surface of the film having a first conducting layer, the conducting layer of the first film contact surface being spaced from the contact surface of the variable resistor element through a spacer element and thus, space being formed therebetween, and one end of the first conducting layer of the first film contact surface being electrically connected to the circuit board; and
a moving component operably connected to the actuator, wherein, thus, the moving component moves relative to the second film contact surface of the film in response to the movement of the actuator and is capable of promoting the first conducting layer of the first film contact surface to form contact with the contact surface of the variable resistor element in a plurality of contact point structures, and thus, effective resistance of the variable resistor element is configured to change in response to promoting the first conducting layer of the first film contact surface to form contact with the contact surface of the variable resistor element in each of the plurality of contact point structures.

2. The electrical switch unit according to claim 1, wherein the variable resistor element is a continuous variable resistor or is connected by connecting a plurality of fixed resistors in series.

3. The electrical switch unit according to claim 1, wherein an exhaust hole that passes through upper and lower surfaces of the circuit board is formed at a position of the circuit board corresponding to the space.

4. The electrical switch unit according to claim 1, wherein one end of the first conducting layer of the first film contact surface is in contact connection with the circuit board.

5. The electrical switch unit according to claim 4, wherein the end of the first conducting layer of the first film contact surface corresponding to the second film contact surface is configured with a contact spring, and under a pressure of the contact spring, the end of the first conducting layer of the first film contact surface can be promoted to be in contact connection with the circuit board.

6. The electrical switch unit according to claim 4, wherein the end of the first conducting layer of the first film contact surface is bonded to the circuit board through a conducting bonding layer.

7. The electrical switch unit according to claim 1, wherein the electrical switch unit further comprises:
a pair of electrical switch contacts, wherein at least one of the pair of electrical switch contacts is operably connected to the actuator; in response to the movement of the actuator from the OFF position to the ON position along the moving axis, the pair of electrical switch contacts is arranged as a closed structure, and power can be supplied to the DC motor from a DC power supply via the pair of electrical switch contacts; and in response to the movement of the actuator from the ON position to the OFF position along the moving axis, the pair of electrical switch contacts is arranged as an opened structure, and in this case, power cannot be supplied to the DC motor from the DC power supply via the pair of electrical switch contacts;
a power module, wherein the power module comprises at least one solid state power switch device for supplying the power from the DC power supply to the DC motor controllably; and
a control module, wherein the control module comprises a control circuit, the control circuit being used for receiving the signaling module signal and outputting a control module signal in response to the received signaling module signal to control the at least one solid state power switch device of the power module, wherein the at least one solid state power switch device supplies the power from the DC power supply to the DC motor controllably to allow the DC motor to operate at a speed corresponding to the movement or position of the sensed actuator.

8. An electrical switch unit for an electrical device, the electrical switch unit being used for controlling an operation of a DC motor of the electrical device, wherein the electrical switch unit comprises:
a shell, wherein the shell accommodates an actuator movably installed in the shell, the actuator being configured to be capable of moving toward an ON position from an OFF position in a direction toward an interior of an opening in the shell along a moving axis and to be capable of moving toward the OFF position from the ON position in a direction toward an exterior of the opening in the shell along the moving axis in response to operations of a finger-operable trigger; and
a signaling module, wherein the signaling module is associated with the electrical switch unit and comprises a signaling circuit, the signaling circuit being used for sensing a movement of the actuator and outputting a signaling module signal that indicates the movement or position of the sensed actuator;
wherein the signaling module comprises:
a circuit board, wherein the circuit board comprises a first region provided with a variable resistor element and a second region having a signal control element, the first region and the second region being arranged to be physically separated and spaced, the variable resistor element having a contact surface of the variable resistor element, and the signal control element having a contact surface of the signal control element;
a film, wherein the film comprises a first film contact surface and a second film contact surface, the first film contact surface of the film having a first conducting layer and a second conducting layer, the first conducting layer and the second conducting layer of the first film contact surface being spaced from the contact surface of the variable resistor element and the contact surface of the signal control element through spacer elements, respectively and thus, space being formed therebetween, and one end of each of the first conducting layer and the second conducting layer of the first film contact surface being electrically connected to the circuit board; and
a moving component operably connected to the actuator, wherein, thus, the moving component moves relative to the second film contact surface of the film in response to the movement of the actuator and is capable of promoting the first conducting layer of the first film contact surface to form contact with the contact surface of the variable resistor element in a plurality of contact point structures, and thus, effective resistance of the variable resistor element is configured to change in response to promoting the first conducting layer of the first film contact surface to form contact with the contact surface of the variable resistor element in each of the plurality of contact point structures;
wherein in response to the movement of the moving component along the second film contact surface of the film and the capability of promoting the second conducting layer of the first film contact surface to form contact with the contact surface of the signal control element in a plurality of contact point structures, thus, effective resistance of the signal control element is configured to change in response to promoting the second conducting layer of the first film contact surface to form contact with the contact surface of the signal control element in each of the plurality of contact point structures; or a circuit of the signal control element is configured to switch signals in response to promoting the second conducting layer of the first film contact surface to form contact with the contact surface of the signal control element in one of the plurality of contact point structures.

9. The electrical switch unit according to claim 8, wherein the variable resistor element is a continuous variable resistor or is connected by connecting a plurality of fixed resistors in series.

10. The electrical switch unit according to claim 8, wherein the variable resistor element is the continuous variable resistor or is connected by connecting the plurality of fixed resistors in series, or is an NC/NO switching circuit.

11. The electrical switch unit according to claim 8, wherein the moving component is a rolling element, the rolling element comprising a first rolling portion and a second rolling portion, the first rolling portion being configured to promote the first conducting layer to form contact with the contact surface of the variable resistor element, and the second rolling portion being configured to promote the second conducting layer to form contact with the contact surface of the signal control element.

12. The electrical switch unit according to claim 8, wherein an exhaust hole that passes through upper and lower surfaces of the circuit board is formed at a position of the circuit board corresponding to the space.

13. The electrical switch unit according to claim 8, wherein one end of each of the first conducting layer and the second conducting layer of the first film contact surface is in contact connection with the circuit board.

14. The electrical switch unit according to claim 13, wherein the end of each of the first conducting layer and the second conducting layer of the first film contact surface corresponding to the second film contact surface is configured with a contact spring, and under a pressure of the contact spring, the end of each of the first conducting layer and the second conducting layer of the first film contact surface can be promoted to be in contact connection with the circuit board.

15. The electrical switch unit according to claim 13, wherein the end of each of the first conducting layer and the second conducting layer of the first film contact surface is bonded to the circuit board through a conducting bonding layer.

16. The electrical switch unit according to claim 8, wherein the electrical switch unit further comprises:
a pair of electrical switch contacts, wherein at least one of the pair of electrical switch contacts is operably connected to the actuator; in response to the movement of the actuator from the OFF position to the ON position along the moving axis, the pair of electrical switch contacts is arranged as a closed structure, and power can be supplied to the DC motor from a DC power supply via the pair of electrical switch contacts; and in response to the movement of the actuator from the ON position to the OFF position along the moving axis, the pair of electrical switch contacts is arranged as an opened structure, and in this case, power cannot be supplied to the DC motor from the DC power supply via the pair of electrical switch contacts;
a power module, wherein the power module comprises at least one solid state power switch device for supplying the power from the DC power supply to the DC motor controllably; and
a control module, wherein the control module comprises a control circuit, the control circuit being used for receiving the signaling module signal and outputting a control module signal in response to the received signaling module signal to control the at least one solid state power switch device of the power module, wherein the at least one solid state power switch device supplies the power from the DC power supply to the DC motor controllably to allow the DC motor to operate at a speed corresponding to the movement or position of the sensed actuator.
